(19) United States
(12) Patent Application Publication
(10) Pub. No.: US 2013/0293257 A1
(43) Pub. Date: Nov. 7, 2013

(54) TESTING SYSTEM FOR POWER SUPPLY UNIT

(71) Applicants: LI LIU, Wuhan City (CN); ZHI-YONG GAO, Wuhan City (CN)

(72) Inventors: LI LIU, Wuhan City (CN); ZHI-YONG GAO, Wuhan City (CN)

(21) Appl. No.: 13/663,586

(22) Filed: Oct. 30, 2012

(30) Foreign Application Priority Data
May 2, 2012 (CN) 201210131587.0

(51) Int. Cl. G01R 31/40

(52) U.S. Cl. 324/764.01

(57) ABSTRACT

A testing system for testing a power supply unit, includes a testing board, an electronic load board, and a capacitor choice circuit. The testing board is connected to a power supply unit to receive a DC voltage from the power supply unit. The testing board includes an output port. The electronic load board is connected to the output port of the testing board. The output port outputs the DC voltage to the electronic load board. The capacitor choice circuit is connected to the output port. The capacitor choice circuit includes a plurality of capacitor assemblies. Each capacitor assembly includes a switch and a capacitor. The capacitor is connected to the output port via the switch. Switches of the plurality of capacitor assemblies are turned on or off in different combinations to obtain different capacitances in the capacitor choice circuit for testing the power supply unit.

### BACKGROUND

1. Technical Field

The present disclosure relates to testing systems, and more particularly to a system for testing power supply units.

2. Description of Related Art

A power supply unit converts an alternating current (AC) voltage into direct current (DC) voltages, and provides the DC voltages to an electronic device. The DC voltages usually are 5V, 12V, and 3.3V voltages. After the power supply unit is being manufactured, an overall test is required to check the power supply unit. For example, the power supply unit may be connected to different capacitors to test a working stability of the power supply unit. However, such a test requires that the power supply unit be connected to different capacitors at different times, which is labor intensive and time-consuming.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of a testing system for testing a power supply unit in accordance with an embodiment.

FIG. 2 is a circuit diagram of a capacitor choice circuit of the testing system of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”.

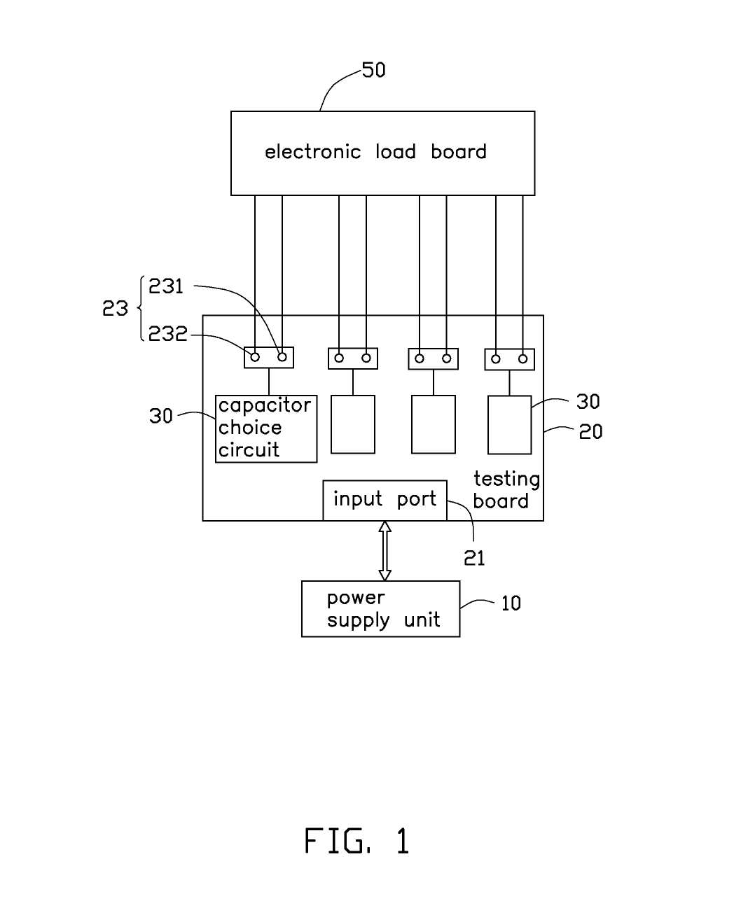

Referring to FIG. 1, a testing system for testing a power supply unit 10 includes a testing board 20, a plurality of capacitor choice circuits 30, and an electronic load board 50.

The testing board 20 includes an input port 21. The input port 21 is connected to the power supply unit 10 to receive a plurality of direct current (DC) voltages outputted by the power supply unit 10. In one embodiment, the plurality of DC voltages includes 5V, 12V, and 3.3V DC voltages. The testing board 20 further includes a plurality of output ports 23. Each of the plurality of output ports 23 includes a first output end 231 and a second output end 232. The first output end 231 outputs a type of DC voltage to the electronic load board 50. The second output end 232 is grounded. The electronic load board 50 includes a plurality of electronic loads for testing the power supply unit 10.

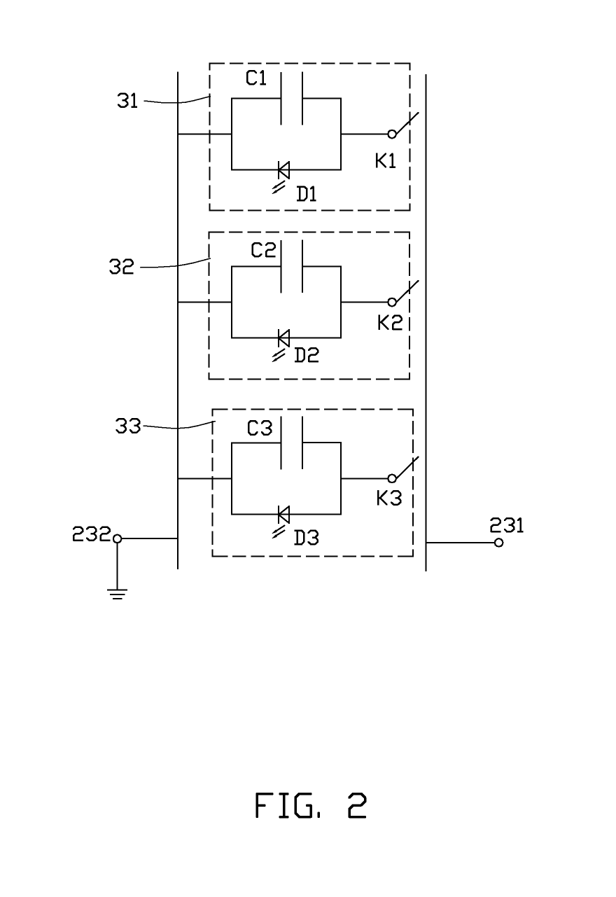

Referring to FIGS. 1 and 2, each of the plurality of output ports 23 is connected to one of the plurality of capacitor choice circuits 30. Each of the plurality of capacitor choice circuits 30 includes a plurality of capacitor assemblies. In one embodiment, the plurality of capacitor assemblies includes a first capacitor assembly 31, a second capacitor assembly 32, and a third capacitor assembly 33.

The first capacitor assembly 31 includes a first capacitor C1, a first light emitting diode (LED) D1, and a first switch K1. The first capacitor C1 is connected to the first LED D1 in parallel. An anode of first LED D1 is connected to the first output end 231 via the first switch K1. When the first switch K1 is turned on, the first capacitor C1 and the first LED D1 are connected to the first output end 231 of a corresponding one of the plurality of output ports 23. A cathode of the first LED D1 is connected to the second output end 232 of the corresponding one of the plurality of output ports 23.

The second capacitor assembly 32 includes a second capacitor C2, a second LED D2, and a second switch K2. The second capacitor C2 is connected to the second LED D2 in parallel. An anode of second LED D2 is connected to the second output end 232 via the second switch K2. When the second switch K2 is turned on, the second capacitor C2 and the second LED D2 are connected to first output end 231 of the corresponding one of the plurality of output ports 23. A cathode of the second LED D2 is connected to the second output end 232 of the corresponding one of the plurality of output ports 23.

The third capacitor assembly 33 includes a third capacitor C3, a third LED D3, and a third switch K3. The third capacitor C3 is connected to the third LED D3 in parallel. An anode of third LED D3 is connected to the second output end 232 via the third switch K3. When the third switch K3 is turned on, the third capacitor C3 and the third LED D3 are connected to first output end 231 of the corresponding one of the plurality of output ports 23. A cathode of the third LED D3 is connected to the second output end 232 of the corresponding one of the plurality of output ports 23.

In one embodiment, the first capacitor C1, the second capacitor C2, and the third capacitor C3 have different capacitances. For example, a capacitance of the first capacitor C1 is 1000 pico farads, a capacitance of the second capacitor C2 is 2000 pico farads, and a capacitance of the third capacitor C3 is 5000 pico farads. For testing the power supply unit 10, one or two or all of the first capacitor C1, the second capacitor C2, and the third capacitor C3 can be connected to the first output end 231, so a plurality of capacitances can be utilized for testing the power supply unit 10. The plurality of capacitances are 1000 pico farads, 2000 pico farads, 5000 pico farads, 3000 pico farads, 6000 pico farads, 7000 pico farads, and 8000 pico farads. In another embodiment, the first capacitor C1, the second capacitor C2, and the third capacitor C3 have a same capacitance, such as 2000 pico farads. Then, the first capacitor C1, the second capacitor C2, and the third capacitor C3 can be coupled to achieve 2000 pico farads, 4000 pico farads, and 6000 pico farads.

To test the power supply unit 10, the power supply unit 10 converts an AC voltage into 5V, 12V, and 3.3V DC voltages. The DC voltages are supplied to the testing board 20 via the input port 21. Each of the plurality of output ports 23 outputs a type of DC voltage to the electronic load board 50. The first switch K1, the second switch K2, and the third switch K3 are turned on or turned off to provide different capacitances for testing the power supply unit 10. For example, when the first switch K1 is turned on and the second switch K2 and third switch K3 are turned off, it is the first capacitor C1 which is connected in the testing circuit and the first light emitting diode D1 is lit.

In the testing system, the first switch K1, the second switch K2, and the third switch K3 are turned on or turned off to provide different capacitances to avoid having to physically disconnect or connect different capacitors one by one.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A testing system for testing a power supply unit, comprising:
a testing board connected to a power supply unit to receive a DC voltage from the power supply unit, the testing board comprising an output port;
an electronic load board connected to the output port of the testing board, the output port being configured to output the DC voltage to the electronic load board; and
a capacitor choice circuit connected to the output port, the capacitor choice circuit comprising a plurality of capacitor assemblies, each of the plurality of capacitor assemblies comprising a switch and a capacitor, the capacitor being connected to the output port via the switch, wherein the switches of the plurality of capacitor assemblies are turned on or tuned off in different combinations to obtain different capacitances in the capacitor choice circuit for testing the power supply unit.

2. The testing system of claim 1, wherein the output port comprises a first output end and a second output end, the first output end outputs the DC voltage to the electronic load board, and the second output end is grounded.

3. The testing system of claim 2, wherein one end of the capacitor is connected to the first output end of the output port via the switch, and another end of the capacitor is connected to the second output end of the output port.

4. The testing system of claim 2, wherein a light emitting diode is connected to the capacitor in parallel.

5. The testing system of claim 4, wherein an anode of the light emitting diode is connected to the first output end via the switch, and a cathode of the light emitting diode is connected to the second output end.

6. The testing system of claim 1, wherein capacitances of the capacitors of the plurality of capacitor assemblies are different.

7. The testing system of claim 1, wherein capacitances of the capacitors of the plurality of capacitor assemblies are same.

8. The testing system of claim 1, where the electronic load board is configure to apply different levels of electronic loads to the power supply unit and to test the power supply unit under the different levels of electronic loads.

9. A testing system for testing a power supply unit, comprising:
a testing board connected to a power supply unit to receive a DC voltage from the power supply unit, the testing board comprising an output port; and
a capacitor choice circuit connected to the output port, the capacitor choice circuit comprising a plurality of capacitor assemblies, each of the plurality of capacitor assemblies comprising a switch, a capacitor, and a light emitting diode, the capacitor and the light emitting diode being connected to each other in parallel, the capacitor and the light emitting diode being connected to the output port via the switch, wherein each of the switch is selectively turned on to connect the capacitor connected to the switch to the output port and light the light emitting diode connected to the switch.

10. The testing system of claim 9, wherein switches of the plurality of capacitor assemblies are turned on or turn off in different combinations to obtain different capacitances in the capacitor choice circuit for testing the power supply unit.

11. The testing system of claim 10, wherein the output port comprises a first output end and a second output end, an electronic load board is connected to the first output end, and the second output end is grounded.

12. The testing system of claim 11, wherein the electronic load board is configured to apply different levels electronic loads to the power supply unit and to test the power supply unit under the different levels of electronic loads.

13. The testing system of claim 11, wherein one end of the capacitor is connected to the first output end of the output port via the switch, and another end of the capacitor is connected to the second output end of the output port.

14. The testing system of claim 11, wherein an anode of the light emitting diode is connected to the first output end via the switch, and a cathode of the light emitting diode is connected to the second output end.

15. The testing system of claim 9, wherein capacitances of the capacitors of the plurality of capacitor assemblies are different.

16. The testing system of claim 9, wherein capacitances of the capacitors of the plurality of capacitor assemblies are same.
